(19) United States
(12) Patent Application Publication
(10) Pub. No.: US 2017/0222755 A1
(43) Pub. Date: Aug. 3, 2017

(54) DECODING MODULE WITH LOGARITHM CALCULATION FUNCTION

(71) Applicant: MStar Semiconductor, Inc., Hsinchu Hsien (TW)

(72) Inventor: Yu Hsien KU, Hsinchu Hsien (TW)

(21) Appl. No.: 15/281,669

(22) Filed: Sep. 30, 2016

Related U.S. Application Data
(60) Provisional application No. 62/288,455, filed on Jan. 29, 2016.

(51) Int. Cl. H04L 1/00

(52) U.S. Cl. CPC H04L 1/0045; H03M 13/1102

(57) ABSTRACT

A decoding module for a communication device includes a first calculation circuit, outputting the larger between a first parameter and a second parameter as a first output parameter; a first arithmetic circuit, calculating a first product of a third parameter and a first slope, and a first difference between a first constant and the first product; a second arithmetic circuit, calculating a second product of the third parameter and a second slope, and a second difference between a second constant and the second product; a second calculation circuit, selecting the largest among a third constant, the first difference and the second difference and generating a second output parameter, wherein the third constant is zero; and an addition circuit, adding the first output parameter and the second output parameter to generate output information, according to which the communication device determines a data bit.

This application claims the benefit of U.S. Provisional Application Ser. No. 62/288,455, filed Jan. 29, 2016, the subject matter of which is incorporated herein by reference.

### BACKGROUND OF THE INVENTION

Field of the Invention

The invention relates in general to a decoding module, and more particularly to a decoding module that implements logarithmic equation calculation by using a plurality of curves.

Description of the Related Art

When a wireless signal is transmitted in a wireless channel of a wireless communication system, the wireless signal may encounter frequency-selective fading and time-selective fading while passing the wireless channel and become distorted. To reduce the effect caused by the wireless channel, a transmitter in the wireless communication system first performs processes such as encoding, modulation and interleaving on transmission data that is then wirelessly transmitted. As such, when a receiver in the wireless communication system receives the wireless signal, the receiver may perform processes such as channel estimation, demodulation and error correction code (ECC) decoding to recover the impaired reception signal.

A stereotypic receiver includes a channel estimator and an ECC decoder. The channel estimator estimates a channel response to recover the distortion in the phase and amplitude of the reception signal. The ECC decoder corrects bits with decision errors in the reception signal according to an ECC. Common ECCs include convolutional code, low-density parity check code (LDPC) and turbo code. As proven to approximate the Shannon Limit of the transmission theory, the turbo code is extensively applied in fields including satellite communication, digital image transmission and 3^{rd} Generation Partnership Project (3GPP) Long-Term Evolution (LTE) in the recently years.

However, when a turbo code decoding process is performed, an ECC decoder may need to implement calculation of logarithmic equations. The calculation of logarithmic equations causes the complexity of the turbo code decoding process to rise significantly in a way that the decoding performance of the receiver is severely degraded. Therefore, there is a need for a simple method for calculating logarithmic equations.

### SUMMARY OF THE INVENTION

The invention is directed to a decoding module that implements logarithmic equation calculation by using a plurality of curves.

According to an aspect of the present invention, a decoding module for a communication device is provided. The communication device receives an input signal, and generates a first parameter and a second parameter according to a data bit in the data signal as well as a first check bit and a second check bit corresponding to the data bit. The decoding module includes: a first calculation circuit, outputting the larger between the first parameter and the second parameter as a first output parameter; a first arithmetic circuit, calculating a first product of a third parameter and a first slope, and a first difference between a first constant and the first product; a second arithmetic circuit, calculating a second product of the third parameter and a second slope, and a second difference between a second constant and the second product; a second calculation circuit, selecting the largest among a third constant, the first difference and the second difference, and generating a second output parameter, wherein the third constant is zero; and an addition circuit, adding the first output parameter and the second output parameter to generate output information, according to which the communication device determines the data bit.

The present invention further discloses a decoding module for a communication device. The communication device receives an input signal, and generates a first parameter and a second parameter according to a data bit in the input signal as well as a first check bit and a second check bit corresponding to the data bit. The decoding module includes: a first calculation circuit, outputting the larger between the first parameter and the second parameter as a first output parameter; a first arithmetic circuit, calculating a first value obtained from substituting a third parameter into a first curve function; a second arithmetic circuit, calculating a second value obtained from substituting the third parameter into a second curve function; a second calculation circuit, selecting the largest among a constant, the first value and the second value, and generating a second output parameter, wherein the constant is zero; and an addition circuit, adding the first output parameter and the second output parameter to generate output information, according to which the communication device determines the data bit. The first curve function and the second curve function are n^{th} degree polynomial functions, and n is greater than or equal to 1.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a schematic diagram of a decoding device according to an embodiment of the present invention;

FIG. 2 is a schematic diagram of a relationship between a logarithmic curve and straight lines according to an embodiment of the present invention;

FIG. 3 is schematic diagram of a decoding device according to an embodiment of the present invention;

FIG. 4 is a calculation circuit according to an embodiment of the present invention;

FIG. 5 is a decoding module according to an embodiment of the present invention; and

FIG. 6 is a decoding module according to an embodiment of the present invention.

### DETAILED DESCRIPTION OF THE INVENTION

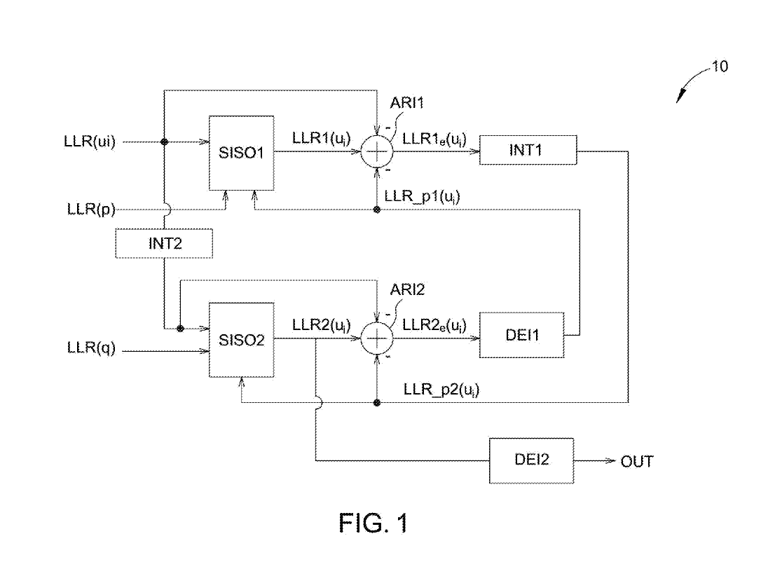

FIG. 1 shows a schematic diagram of a decoding device 10 according to an embodiment of the present invention. The decoding device 10 is applied to a turbo code decoder of a communication system to generate output information OUT of a data bit ui. As shown in FIG. 1, the decoding device 10 includes soft-in-soft-out (SISO) decoding modules SISO1 and SISO2, arithmetic circuits ARI1 and ARI2, interleavers INT1 and INT2, and deinterleavers DEI1 and DEI2. The decoding device 10 has three sets of input information LLR(ui), LLr(p) and LLR(q), where p and q are check bits of the data bit ui, and LLR(ui), LLR(p) and LLR(q) are log-likelihood ratios (LLR) of the data bit ui and the check bits p and q, respectively. The SISO decoding module SISO1 generates extrinsic information LLR1(ui) according to the input information LLR(ui) and LLR(p) and a priori information LLR_p1(ui). The arithmetic circuit ARI1 subtracts the input information LLR(ui) and the a priori information LLR_p1(ui) from the extrinsic information LLR1(ui) to generate extrinsic information LLR1e(ui) to the interleaver INT1, to cause the interleaver INT1 to rearrange the extrinsic information LLR1e(ui) to generate a priori information LLR_p2 outputted to the SISO decoding module SISO2. Similarly, the SISO decoding module SISO2 generates extrinsic information LLR2(ui) according to the interleaved input information LLR(ui), input information LLR(q) and a priori information LLR_p2(ui). The arithmetic circuit ARI2 subtracts the interleaved input information LLR(ui) and a priori information LLR_p2(ui) from the extrinsic information LLR2(ui) to generate extrinsic information LLR2e(ui) to the deinterleaver DEI1, to cause the deinterleaver DEI1 to rearrange the extrinsic information LLR2e(ui) to generate a priori information LLR_p1(ui) outputted to the SISO decoding module SISO1. By repeating the above iterative decoding process, the decoding device 10 is able to generate reliable soft output information OUT. Thus, the communication system may determine the value of the data bit ui according to the output information OUT.

To perform the iterative decoding process, the decoding device 10 may need to support a logarithm calculation function. For example, when the LLR is calculated, the SISO decoding modules SISO1 and SISO2 may need to calculate an equation below:

ln(e^{A}+e^{B}) (1)

In the SISO decoding module SISO1, the parameters A and B may be values generated according to the input information LLR(ui) and LLR(p) and the extrinsic information LLR1(ui). In the SISO decoding module SISO2, the parameters A and B may be values generated according to the input information LLR(p) and LLR(q) and the extrinsic information LLR2(ui). Equation (1) may be simplified as:

ln(e^{A}+e^{B})=max(A, B)+llr_{scale}*ln(1+e^{-d}) (2)

In equation (2),

$$d = \vert \frac{1}{{llr}_{scale}} ⋆ \vert A - B \vert \vert$$

and llr_{scale} is a ratio parameter.

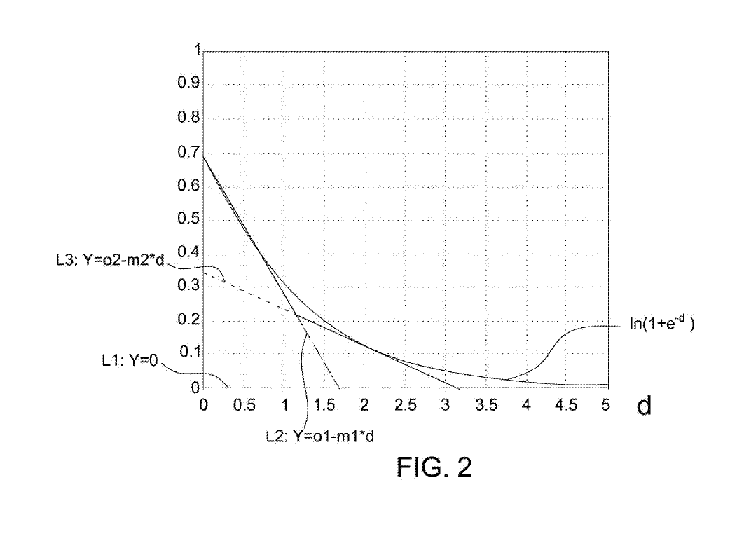

In one embodiment, the SISO decoding modules SISO1 and SISO2 may use three straight lines L1 to L3 to approximate the value of ln(1+e^{-d}) to reduce the hardware costs of implementing the logarithm calculation function. FIG. 2 depicts ln(1+e^{-d}) and the straight lines L1 to L3. In FIG. 2, the straight lines L1 to L3 may be represented by following functions:

L1: Y=0 (3)

L2: Y=o1−m1*d (4)

L3: Y=o2−m2*d (5)

In the above equations, (−m1) and (−m2) are slopes of the straight lines L2 and L3, respectively, and o1 and o2 are constant terms of the straight lines L2 and L3, respectively. In one embodiment, the constant terms o1 and o2 and the slopes (−m1) and (−m2) may be obtained by using a least square method. As shown in FIG. 2, in this embodiment, the largest value among the straight lines L1 to L3 is used to approximate the value of ln(1+e^{-d}) (i.e., ln(1+e^{-d}≅max(0,o1−m1*d,o2−m2*d)). In the above situation, equation (2) may be re-written as:

ln(e^{A}+e^{B})=max(A, B)+llr_{scale}*max(0,o1−m1*d,o2−m2*d) (6)

It is known from equation (6) that, by approximating the value of ln(1+e^{-d}) using the straight lines L1 to L3, the embodiment of the present invention is able to complete the calculation of a natural logarithm through a simple calculation process, hence significantly reducing the hardware costs of implementing the logarithm calculation function.

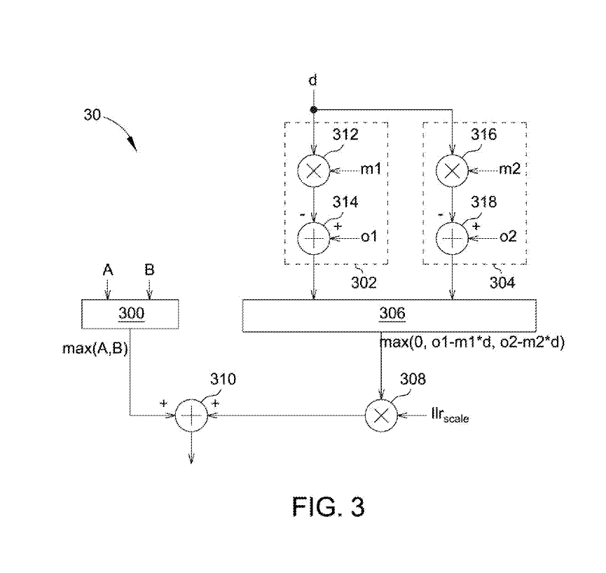

According to different applications and design concepts, hardware for implementing the logarithm calculation function may be realized through various methods. FIG. 3 shows a schematic diagram of a decoding module 30 according to an embodiment of the present invention. The decoding module 30 may be used in the SISO decoding modules SISO1 and SISO2 in FIG. 1 to realize the logarithmic function. As shown in FIG. 3, the decoding module 30 includes calculation circuits 300 and 306, arithmetic circuits 302 and 304, a multiplication circuit 308 and an addition circuit 310. The calculation circuit 300 receives parameters A and B, and outputs the larger between the parameters A and B to the addition circuit 310. The arithmetic circuit 302, including a multiplier 312 and an adder 314, calculates a difference of subtracting a product of a parameter d and a slope m1 from a constant term o1, and outputs the difference calculated to the calculation circuit 306. Wherein, the parameter

$$d = \vert \frac{1}{{llr}_{scale}} ⋆ \vert A - B \vert \vert ,$$

and llr_{scale} is a ratio parameter. Similarly, the arithmetic circuit 304, including a multiplier 316 and an adder 318, calculates a difference of subtracting a product of the parameter d and a slope m2 from a constant term o2, and outputs the difference calculated to the calculation circuit 306. After receiving the differences calculated by the arithmetic circuits 304 and 306, the calculation circuit 310 outputs the larger between the received parameters to the multiplication circuit 308. The multiplication circuit 308 multiplies the output from the calculation circuit 310 by the ratio parameter llr_{scale}, and outputs the product to the addition circuit 310. The addition circuit 310 adds up the received signals to generate a calculation result of equation (6) to realize the logarithm calculation function.

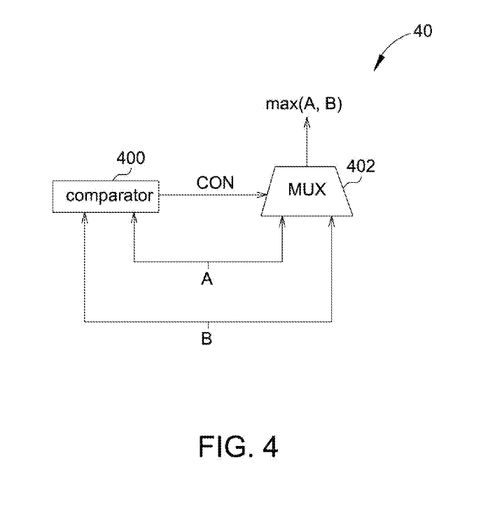

FIG. 4 shows a schematic diagram of a calculation circuit 40 according to an embodiment of the present invention. The calculation circuit 40 may be implemented as the calculation circuit 300 in FIG. 3. In FIG. 4, the calculation circuit 40 includes a comparator 400 and a multiplexer (MUX) 402. The comparator 400 compares the values of the parameters A and B, and accordingly outputs a control signal CON to the multiplexer 402. According to the control signal CON, the multiplexer 402 outputs the larger between the input parameters A and B. One person ordinary skilled in the art may implement the calculation circuit 306 based on an architecture similar to that of the calculation circuit 400 in FIG. 4, and such repeated details are omitted for brevity.

Further, equation (6) may be re-written as:

$$\begin{matrix}ln = ( {e}^{A} + {e}^{B} ) \\ = max ( A , B ) + {llr}_{scale} ⋆ max ( 0 , o 1 - m l ⋆ d , o 2 - m 2 ⋆ d ) \\ = max ( A , B ) + max ( 0 , {llr}_{scale} ⋆ o 1 - \\ {llr}_{scale} ⋆ m 1 ⋆ d , {llr}_{scale} ⋆ o 2 - {llr}_{scale} ⋆ m 2 ⋆ d ) \\ = max ( A , B ) + max ( 0 , C 1 - m 1 ⋆ D , C 2 - m 2 ⋆ D )\end{matrix} \qquad ( 7 )$$

Wherein C1=llr_{scale}*o1, C2=llr_{scale}*o2, and

$$D = {llr}_{scale} ⋆ \vert \frac{1}{{llr}_{scale}} ⋆ \vert A - B \vert \vert = \vert A - B \vert .$$

In equation (7), the ratio parameter llr_{scale} is integrated into the calculation of max(0,o1−m1*d,o2−m2*d). Known from equation (7), by modifying the constant terms and variables of straight line functions for approximating the parameter of 14 +e ^{d}), the logarithm calculation can be further simplified.

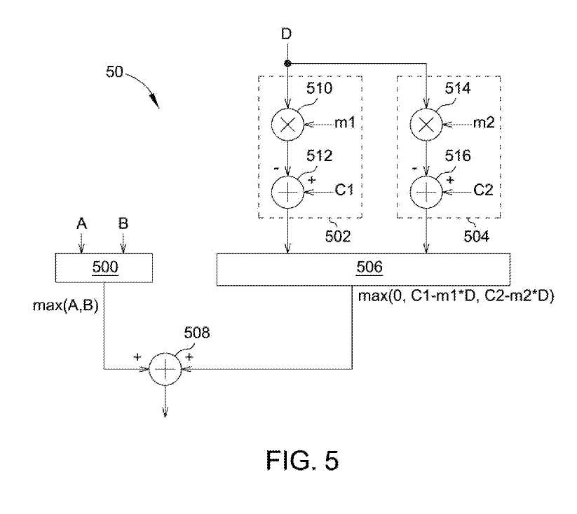

FIG. 5 shows a schematic diagram of a decoding module 50 according to an embodiment of the present invention. The decoding module 50 may be used in the SISO decoding modules SISO1 and SISO2 in FIG. 1 to implement the logarithm calculation function. As shown in FIG. 5, the decoding module 50 includes calculation circuits 500 and 506, arithmetic circuits 502 and 504, and an addition circuit 508. The calculation circuit 500 receives parameters A and B, and outputs the larger between the parameters A and B to the addition circuit 508. The arithmetic circuit 502, including a multiplier 510 and an adder 512, calculates a difference of subtracting a product of a parameter D and a slope m1 from a constant term C1, and outputs the difference calculated to the calculation circuit 506. Similarly, the arithmetic circuit 504, including a multiplier 514 and an adder 516, calculates a difference of subtracting a product of the parameter D and a slope m2 from a constant term C2, and outputs the difference calculated to the calculation circuit 506. In this embodiment, as the ratio parameter llr_{scale} is merged with the constant terms C1 and C2 and the parameter D, the calculation circuit 510 may directly output the larger of the received parameters to the addition circuit 508. The addition circuit 508 adds the received signals to generate a calculation result of equation (7) to implement the logarithm calculation function. Compared to the calculation circuit 300 in FIG. 3, the calculation circuit 500 saves one multiplier, hence further reducing hardware costs of implementing the logarithm calculation function.

According to different applications and design concepts, one person ordinary skilled in the art can make appropriate variations and modifications based on the above embodiments. For example, the decoding modules 30 and 50 may be applied to any operation device needing to implement the logarithm calculation function (e.g., calculating a posterior probability) instead of being applied to only turbo code decoders.

In one embodiment, the straight lines L1 to L3 for approximating ln(1+e^{-d}) may be altered to multiple-power functions (e.g., an n^{th} degree polynomial function, where n is greater or equal to 1). Coefficients of the multiple-power function may be obtained by, for example but not limited to, polynomial fitting calculation. In this embodiment, the arithmetic circuit 302 in FIG. 3 may substitute the parameter d into a curve function CUR1, and output a first value obtained to the calculation circuit 306. Similarly, the arithmetic circuit 304 substitutes the parameter d into another curve function CUR2, and outputs a second value obtained to the calculation circuit 306. Thus, the decoding module 30 is able to approximate a logarithmic curve using a plurality of curves to implement logarithm calculation.

Further, the number of straight lines used for approximating ln(1+e^{-d}) may be appropriately adjusted. In one embodiment, the number of straight lines used for approximating ln(1+e^{-d}) may be changed from 3 to 4 (as the straight lines L1 to L3 in FIG. 2 and a newly added straight line L4). In this embodiment, equation (2) may be re-written as:

ln(e^{A}+e^{B})=max(A, B)+llr_{scale}*max(0,o1−m1*d,o2−m2*d,o3−m3*d) (8)

In equation (8), (−m1), (−m2) and (−m3) are slopes of the straight lines L2 to L4, respective, o1 to o3 are constant terms of the straight lines L2 to L4, respectively, and L1 is a straight line of Y=0.

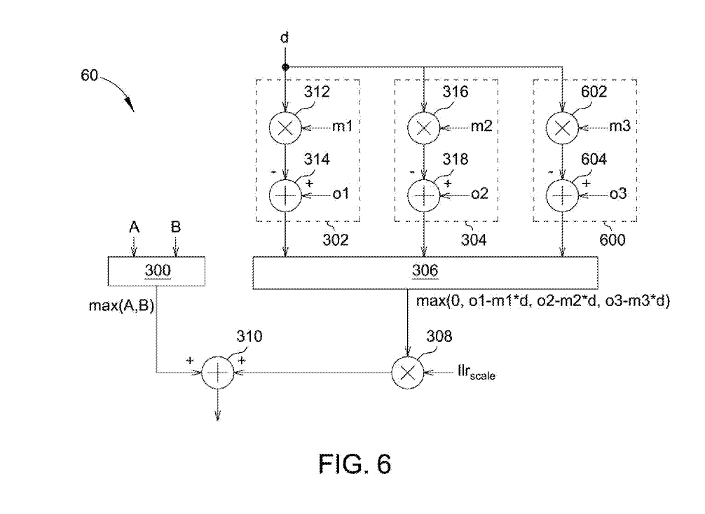

FIG. 6 shows a schematic diagram of a decoding module 60 according to an embodiment of the present invention. The decoding module 60 may be applied in the SISO decoding modules SISO1 and SISO2 to implement the logarithm calculation function. Similar to the decoding module 30 in FIG. 3, the decoding module 60 has signals of similar functions and components represented by the same denotations. Compared to the decoding module 30 in FIG. 3, the decoding module 60 includes an additional arithmetic circuit 600. The arithmetic circuit 600, including a multiplier 602 and an adder 604, calculates a difference of subtracting a product of a parameter d and a slope m3 from a constant term o3, and outputs the difference calculated to the calculation circuit 306. The calculation circuit 306 is modified to outputting the largest among the differences calculated by the calculation circuits 302, 304 and 600 to the multiplication circuit 308. As such, after adding the received signals, the addition circuit 310 is able to generate a calculation result of equation (8) to implement the logarithm calculation function.

In conclusion, by approximating a logarithm curve using a plurality of straight lines, the decoding device of the embodiments implements the logarithm calculation function with a simple hardware structure, thereby significantly reducing hardware costs and operation costs.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A decoding module, applied to a communication device, the communication device receiving an input signal and generating a first parameter and a second parameter according to a data bit of the input signal and a first check bit and a second check bit corresponding to the data bit, the decoding module comprising:
a first calculation circuit, outputting the larger between the first parameter and the second parameter as a first output parameter;
a first arithmetic circuit, calculating a first product of a third parameter and a first slope, and a first difference between a first constant and the first product;
a second arithmetic circuit, calculating a second product of the third parameter and a second slope, and a second difference between a second constant and the second product;
a second calculation circuit, selecting the largest among a third constant, the first difference and the second difference, and generating a second output parameter, wherein the third constant is zero; and
an addition circuit, adding the first output parameter and the second parameter to generate output information;
wherein, the communication device determines the data bit according to the output information.

2. The decoding module according to claim 1, further comprising:
a multiplication circuit, multiplying the largest among the third constant, the first difference and the second difference by a ratio parameter to generate a result as the second output parameter;
wherein, the third parameter is an absolute value of a product of a reciprocal of the ratio parameter and an absolute difference between the first parameter and the second parameter.

3. The decoding module according to claim 1, wherein the third parameter is an absolute value of a difference between the first parameter and the second parameter.

4. The decoding module according to claim 1, wherein the first calculation circuit comprises:
a comparator, comparing the first parameter and the second parameter to generate a control signal indicating a value relationship between the first parameter and the second parameter; and
a multiplexer, selecting one of the first parameter and the second parameter as the first output parameter according to the control signal.

5. The decoding module according to claim 1, wherein the first arithmetic circuit comprises:
a multiplier, calculating a first product of the third parameter and the first slope; and
an adder, calculating the first difference between the first constant and the first product.

6. A decoding module, applied to a communication device, the communication device receiving an input signal and generating a first parameter and a second parameter according to a data bit of the input signal and a first check bit and a second check bit corresponding to the data bit, the decoding module comprising:
a first calculation circuit, outputting the larger between the first parameter and the second parameter as a first output parameter;
a first arithmetic circuit, calculating a first value obtained from substituting a third parameter into a first curve function;
a second arithmetic circuit, calculating a second value obtained from substituting the third parameter into a second curve function;
a second calculation circuit, selecting the largest among a constant, the first value and the second value and generating a second output parameter, wherein the constant is zero; and
an addition circuit, adding the first output parameter and the second output parameter to generate output information;
wherein the communication device determines the data bit according to the output information, the first curve function and the second curve function are n^{th} functions, and n is greater than or equal to 1.

7. The decoding module according to claim 6, further comprising:
a multiplication circuit, multiplying the largest among the third constant, the first difference and the second difference by a ratio parameter to generate a result as the second output parameter;
wherein, the third parameter is an absolute value of a product of a reciprocal of the ratio parameter and an absolute difference between the first parameter and the second parameter.

8. The decoding module according to claim 6, wherein the third parameter is an absolute value of a difference between the first parameter and the second parameter.

9. The decoding module according to claim 6, wherein the first calculation circuit comprises:
a comparator, comparing the first parameter and the second parameter to generate a control signal indicating a value relationship between the first parameter and the second parameter; and
a multiplexer, selecting one of the first parameter and the second parameter as the first output parameter according to the control signal.
